(19) United States
(12) Patent Application Publication
(10) Pub. No.: US 2013/0082228 A1
(43) Pub. Date: Apr. 4, 2013

(54) Memory Device Using Multiple Tunnel Oxide Layers

(71) Applicants: LOUIS PARRILLO, AUSTIN, TX (US); RENE MEYER, ATHERTON, CA (US); JIAN WU, SAN JOSE, CA (US); DAVID EGGLESTON, SAN JOSE, CA (US); LIDIA VEREEN, SAN RAMON, CA (US)

(72) Inventors: LOUIS PARRILLO, AUSTIN, TX (US); RENE MEYER, ATHERTON, CA (US); JIAN WU, SAN JOSE, CA (US); DAVID EGGLESTON, SAN JOSE, CA (US); LIDIA VEREEN, SAN RAMON, CA (US)

(73) Assignee: UNITY SEMICONDUCTOR CORPORATION, SUNNYVALE, CA (US)

(21) Appl. No.: 13/250,772

(22) Filed: Sep. 30, 2011

(51) Int. Cl. H01L 47/00

(52) U.S. Cl. 257/4; 257/E47.001

(57) ABSTRACT

A memory element (ME) including at least one layer of conductive metal oxide (CMO) that includes mobile oxygen ions and including at least two layers of insulating metal oxide (IMO) is disclosed. In one configuration a layer of IMO that is directly in contact with a CMO layer is specifically selected so that a material of the IMO layer is non-reactive with a material of the CMO. In another configuration, at least one pair of adjacent IMO layers are made from materials having different band gaps operative to an generate an internal electric field positioned in the layers and present in the at least two adjacent IMO layers in the absence of electrical power. The internal electric field can be a static electric field. The IMO and/or CMO layers can be deposited in part or in whole using ALD, PEALD, or nano-deposition. The ME can be formed BEOL.

### CROSS-REFERENCE TO RELATED APPLICATIONS

This application is related to: pending U.S. patent application Ser. No. 12/661,678, filed on Mar. 22, 2010, and titled “Immersion Platinum Plating Solution”; U.S. patent application Ser. No. 12/454,322, filed on May 15, 2009, now U.S. Published Application No. 2010/0159688, and titled “Device Fabrication”; U.S. patent application Ser. No. 11/095,026, filed Mar. 30, 2005, and published as U.S. Pub. No. 2006/0171200, and titled “Memory Using Mixed Valence Conductive Oxides”; U.S. patent application Ser. No. 12/653,836, filed Dec. 18, 2009, and published as U.S. Pub. No. 2010/0157658, and titled “Conductive Metal Oxide Structures In Non-Volatile Re-Writable Memory Devices”; U.S. Pat. No. 7,897,951, issued on Mar. 1, 2011, and titled “Continuous Plane Of Thin-Film Materials For A Two-Terminal Cross-Point Memory”; U.S. patent application Ser. No. 12/653,851, filed Dec. 18, 2009, and published as U.S. Pub. No. 2010/0159641, and titled “Memory Cell Formation Using Ion Implant Isolated Conductive Metal Oxide”; pending U.S. patent application Ser. No. 13/171,350, Filed Jun. 28, 2011, and titled “Multilayer Cross-Point Memory Array Having Reduced Disturb Susceptibility”; pending U.S. patent application Ser. No. 13/210,342, Filed Aug. 15, 2011, and titled “Structures And Methods For Facilitating Enhanced Cycling Endurance Of Memory Accesses To Re-Writable Non-Volatile Two-Terminal Memory Elements”; pending U.S. patent application Ser. No. 13/210,292, Filed Aug. 15, 2011, and titled “Vertical Cross-Point Arrays For Ultra-High-Density Memory Applications”; U.S. Pat. No. 7,995,371, issued on Aug. 9, 2011, and titled “Threshold Device For A Memory Array”; and U.S. Pat. No. 7,884,349, issued on Feb. 8, 2011, and titled “Selection Device for Re-Writable Memory”, all of which are hereby incorporated by reference in their entirety for all purposes.

### FIELD OF THE INVENTION

The present invention relates generally to non-volatile memory devices. More specifically, present invention relates to non-volatile RRAM memory devices.

### BACKGROUND

Conventional resistive random access memory (RRAM) devices can be plagued by reliability and performance problems due to interface reactions between different thin-film materials that are in contact with each other, to variations in thickness of thin-film layers of memory material, and choice of fabrication techniques, just to name a few. Those reliability and performance problems can adversely affect device parameters including but not limited to data retention, cycling, and memory effect.

There are continuing efforts to improve non-volatile memory structures, and fabrication technology.

### BRIEF DESCRIPTION OF THE DRAWINGS

Various embodiments of the invention are disclosed in the following detailed description and the accompanying drawings:

FIG. 1 depicts a cross-sectional view of an example of a memory element including at least one CMO layer and at least two IMO layers;

FIG. 2 depicts a cross-sectional view of another example of a memory element including at least one CMO layer and at least two IMO layers;

FIGS. 3A and 3B depict cross-sectional views of different embodiments of the memory element of FIG. 1;

FIGS. 4A and 4B depict cross-sectional views of different embodiments of the memory element of FIG. 2;

FIGS. 5A and 5B depict more detailed cross-sectional views of memory material layers of the embodiments depicted in FIGS. 3A and 3B;

FIGS. 6A and 6B depict more detailed cross-sectional views of memory material layers of the embodiments depicted in FIGS. 4A and 4B;

FIG. 7A depicts a cross-sectional view of one example of a mobile oxygen ion transport before and after a programming operation on a memory element;

FIG. 7B depicts a cross-sectional view of another example of a mobile oxygen ion transport before and after a programming operation on a memory element;

FIG. 8A depicts a cross-sectional view of one example of a mobile oxygen ion transport before and after an erase operation on a memory element;

FIG. 8B depicts a cross-sectional view of another example of a mobile oxygen ion transport before and after an erase operation on a memory element;

FIG. 9 depicts a profile view of a multi-layer two-terminal cross-point array structure that includes inverted and non-inverted memory elements;

FIG. 10A depicts a cross-sectional view of one example of adjacent IMO layers having different band gaps and including a internal electric field;

FIG. 10B depicts a cross-sectional view of another example of adjacent IMO layers having different band gaps and including a internal electric field;

FIG. 10C depicts a cross-sectional view of one example of multiple adjacent IMO layers where at least two of the layers have different band gaps;

FIG. 11A depicts a cross-sectional view of an example of an IMO layer having a stoichiometry that varies as a function of thickness within the IMO layer;

FIG. 11B depicts a cross-sectional view of an example of a CMO layer having a stoichiometry that varies as a function of thickness within the CMO layer;

FIG. 11C depicts a cross-sectional view of multiple IMO layers having layer specific permeability to mobile oxygen ions during write operations to a memory element;

FIG. 11D depicts a cross-sectional view of multiple IMO layers in which one or more of the layers comprise a soft-blended multi-phase IMO layer;

FIG. 12A depicts a cross-sectional view of one example of a first electrode structure;

FIG. 12B depicts a cross-sectional view of another example of a first electrode structure;

FIG. 12C depicts a cross-sectional view of one example of a second electrode structure;

FIG. 12D depicts a cross-sectional view of another example of a second electrode structure;

FIG. 13A depicts a profile cross-sectional view of a non-inverted discrete two-terminal memory element positioned between a cross-point of two conductive array lines;

FIG. 13B depicts a profile cross-sectional view of an inverted memory element positioned between a cross-point of two conductive array lines;

FIG. 13C depicts a profile cross-sectional view of one example of a memory element positioned between a cross-point of two conductive array lines and including an optional selection device;

FIG. 13D depicts a cross-sectional view of another example of a memory element positioned between a cross-point of two conductive array lines and including an optional selection device; and

FIG. 14 depicts a graph of one example of a non-linear I-V characteristic of a discrete two-terminal memory element.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description. The described fabrication techniques may be varied and are not limited to the examples provided.

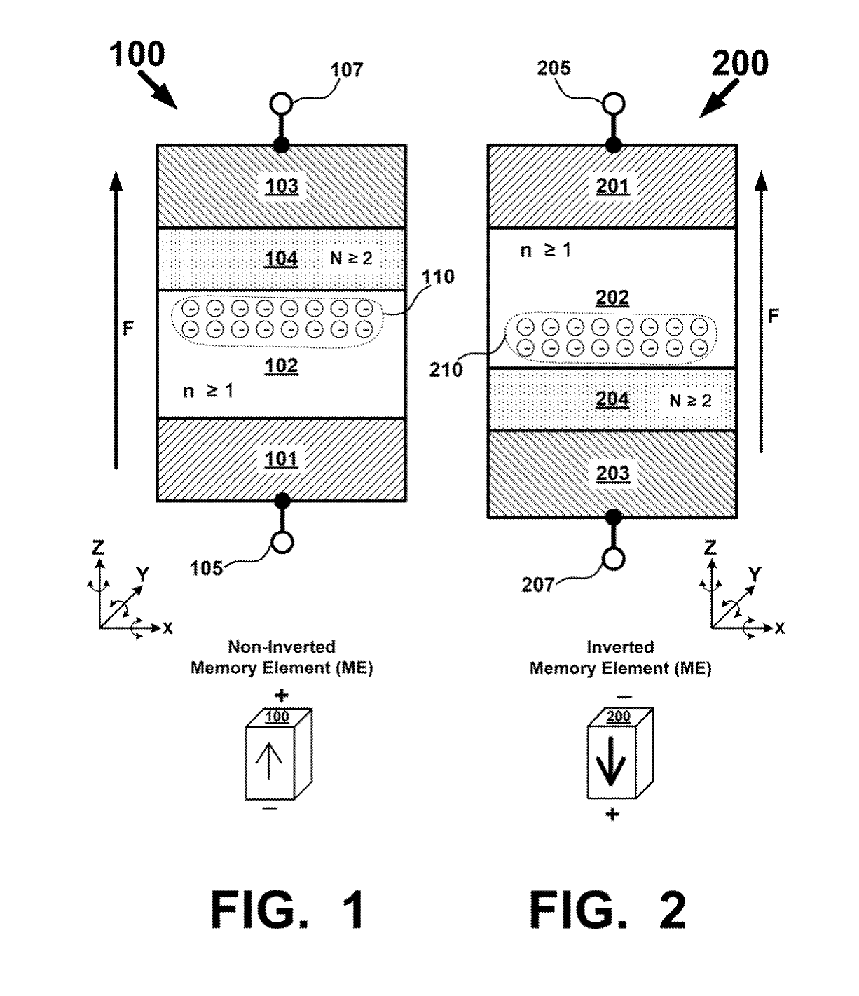

FIG. 1 depicts a cross-sectional view of one example of a discrete re-writeable non-volatile two-terminal memory element (ME) 100. ME 100 includes a first electrode structure 101, a second electrode structure 103, and at least one layer of conductive metal oxide (CMO) 102 that is in direct contact with the first electrode structure 101. Here, at least one layer of CMO 102 means that there are at least n≧1 layers of CMO where n is an integer that is greater than or equal to 1. Although only one layer 102 is depicted, the ME 100 can include two or more layers of CMO 102 as will de described below. CMO 102 includes mobile oxygen ions 110 positioned in the CMO 102 and at least a portion of the mobile oxygen ions 110 are movable into and out of the CMO 102 during write operations to the ME 100 as will be described below. ME 100 also includes N distinct layers of insulating metal oxide (IMO) 104 that are in direct contact with one another such that there are N≧2 layers of IMO 104 in ME 100. Although only one layer 104 is depicted, there are at least two layers of IMO 104 in each ME 100 and each layer has an individual layer thickness that is specifically configured to enable electron tunneling during data operations to the ME 100. Examples of data operations include but are not limited to read operations, restore operations, write operations, program operations, and erase operations, just to name a few. Of the N≧2 distinct layers of IMO 104 in ME 100, a first layer of the N distinct layers is in direct contact with the at least one layer of CMO 102 and is made from an IMO material specifically selected to be non-reactive with a material of the at least one layer of CMO 102 that the first layer is in direct contact with. The first layer is an electrolyte to the mobile oxygen ions 110 and is permeable to the mobile oxygen ions 110 during write operations to the ME 100, such that at least a portion of the mobile oxygen ions 110 are transported into or out of at least the first layer of the N≧2 layers of IMO 104. In that there are N≧2 layers of IMO 104 in ME 100, a last layer of the N distinct layers is in direct contact with the second electrode structure 103. In some embodiments, the first and second electrode structures may be referred two as first and second terminal structures. Typically, electrodes or terminals are operative to electrically couple the ME 100 with other electrically conductive structures such as the conductive array lines of a cross-point array and/or with circuitry that applies voltages for data operations to the ME 100, such as reading and writing data to the ME 100, for example. The at least one layer of CMO 102 and the N distinct layers of IMO 104 are electrically in series with each other and with the first and second electrode structures.

FIG. 2 depicts a cross-sectional view of another example of a discrete re-writeable non-volatile two-terminal memory element (ME) 200. ME 200 includes a first electrode structure 201, a second electrode structure 203, and at least one layer of conductive metal oxide (CMO) 202 that is in direct contact with the first electrode structure 201. Here at least one layer of CMO 202 means that there are at least n≧1 layers of CMO 102 where n is an integer that is greater than or equal to 1. Although only one layer 202 is depicted, the ME 200 can include two or more layers of CMO 202 as will de described below. CMO 202 includes mobile oxygen ions 210 positioned in the CMO 202 and at least a portion of the mobile oxygen ions 210 are movable into and out of the CMO 202 during write operations to the ME 200 as will be described below. ME 200 also includes N distinct layers of insulating metal oxide (IMO) 204 that are in direct contact with one another such that there are N≧2 layers of IMO 202 in ME 200. Although only one layer 204 is depicted, there are at least two layers of IMO 104 in each ME 200 and each layer has an individual layer thickness that is specifically configured to enable electron tunneling during data operations to the ME 200. Examples of data operations include but are not limited to read operations, restore operations, write operations, program operations, and erase operations, just to name a few. Of the N≧2 distinct layers of IMO 204 in ME 200, a first layer of the N distinct layers is in direct contact with the at least one layer of CMO 202 and is made from an IMO material specifically selected to be non-reactive with a material of the at least one layer of CMO 202 that the first layer is in direct contact with. The first layer is an electrolyte to the mobile oxygen ions 210 and is permeable to the mobile oxygen ions 210 during write operations to the ME 200, such that at least a portion of the mobile oxygen ions 210 are transported into or out of at least the first layer of the N≧2 layers of IMO 204. In that there are N≧2 layers of IMO 204 in ME 200, a last layer of the N distinct layers is in direct contact with the second electrode structure 203. In some embodiments, the first and second electrode structures may be referred two as first and second terminal structures. Typically, electrodes or terminals are operative to electrically couple the ME 200 with other electrically conductive structures such as the conductive array lines of a cross-point array and/or with circuitry that applies voltages for data operations to the ME 200 for reading and writing data to the ME 200. In FIG. 1, first and second electrode structures 101 and 103 can be electrically coupled with nodes 105 and 107 respectively, and nodes 105 and 107 may represent the other electrically conductive structures (e.g., conductive array lines). Similarly, in FIG. 2, first and second electrode structures 201 and 203 can be electrically coupled with nodes 205 and 207 respectively, and nodes 205 and 207 may represent the other electrically conductive structures (e.g., conductive array lines).

The structure for ME 100 depicted in FIG. 1 may be referred to as a non-inverted ME 100 and will be depicted with a light arrow pointing upward in subsequent drawing figures and the structure for ME 200 depicted in FIG. 2 may be referred to as an inverted ME 200 and may be depicted with a heavy arrow pointing downward in subsequent drawing figures. A fabrication order F may be used to determine if a non-inverted ME 100 or an inverted ME 200 is formed as a result of the fabrication process. In some embodiments, all ME's (100, 200) can be fabricated back-end-of-the-line (BEOL) over a substrate (e.g., a semiconductor substrate such as a silicon wafer or die) that includes front-end-of-the-line (FEOL) circuitry with at least a portion of the circuitry configured to perform data operations on a ME or a plurality of ME's. Here, the fabrication order F may proceed along the +Z axis with each layer of thin-film material for the ME being deposited or otherwise formed and processed.

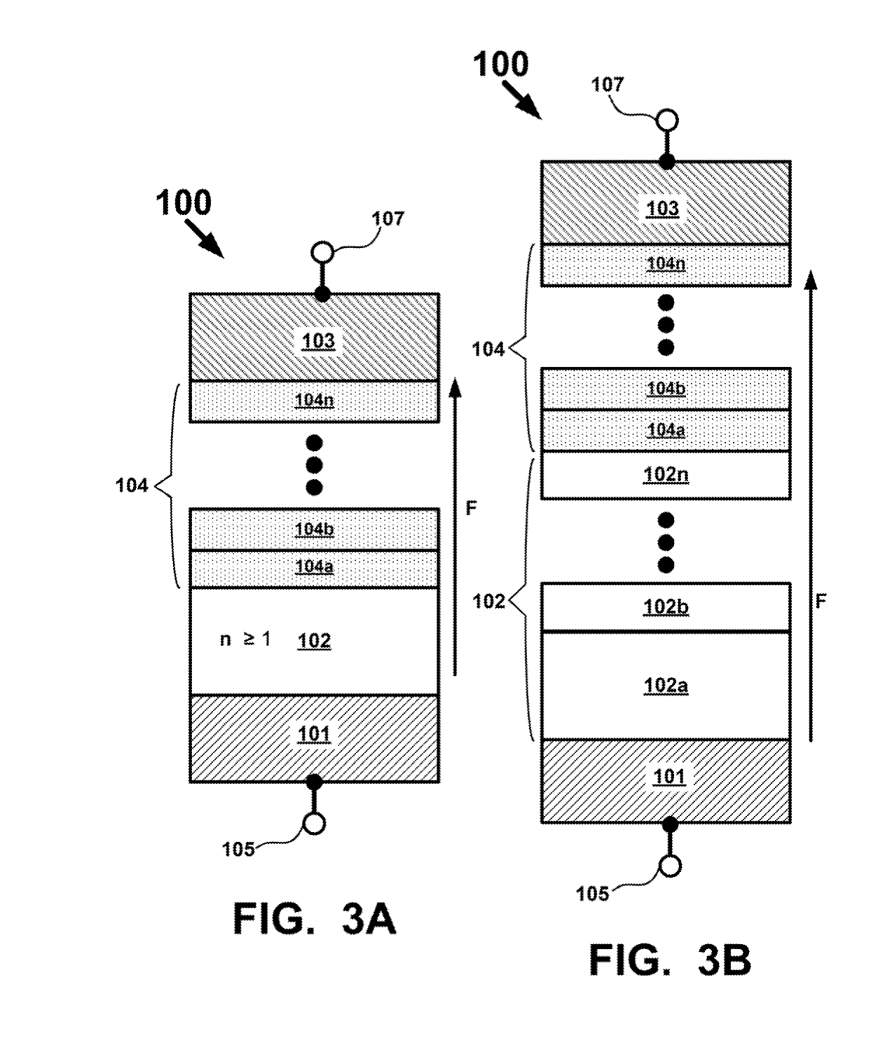

Moving now to FIG. 3A, a cross-sectional view of ME 100 depicts in greater detail the N≧2 distinct layers of IMO 204 as distinct layers 104a, 104b, up to an Nth layer 104n. Here, the minimum number of IMO layers 104 in ME 100 comprises layers 104a and 104b and the first layer is layer 104a as it is the layer that is in direct contact with the uppermost layer of the n≧1 layers of CMO 102. Of course, in some implementations there will be more than the minimum of two layers and the “” up to layer 104n is intended to make it clear that the ME 100 can include a third, a fourth, a fifth, up to an Nth IMO layer.

In FIG. 3B, a cross-sectional view of ME 100 depicts in greater detail the N≧2 distinct layers of IMO 204 as distinct layers 104a, 104b, up to an Nth layer 104n, as well as n≧1 distinct layers of CMO 204 denoted as CMO layers 102a, 102b, up to nth layer 102n. Of course, in some implementations there will be more than the minimum of one layer of CMO and the “” up to layer 102n is intended to make it clear that the ME 100 can include a second, a third, up to an nth CMO layer.

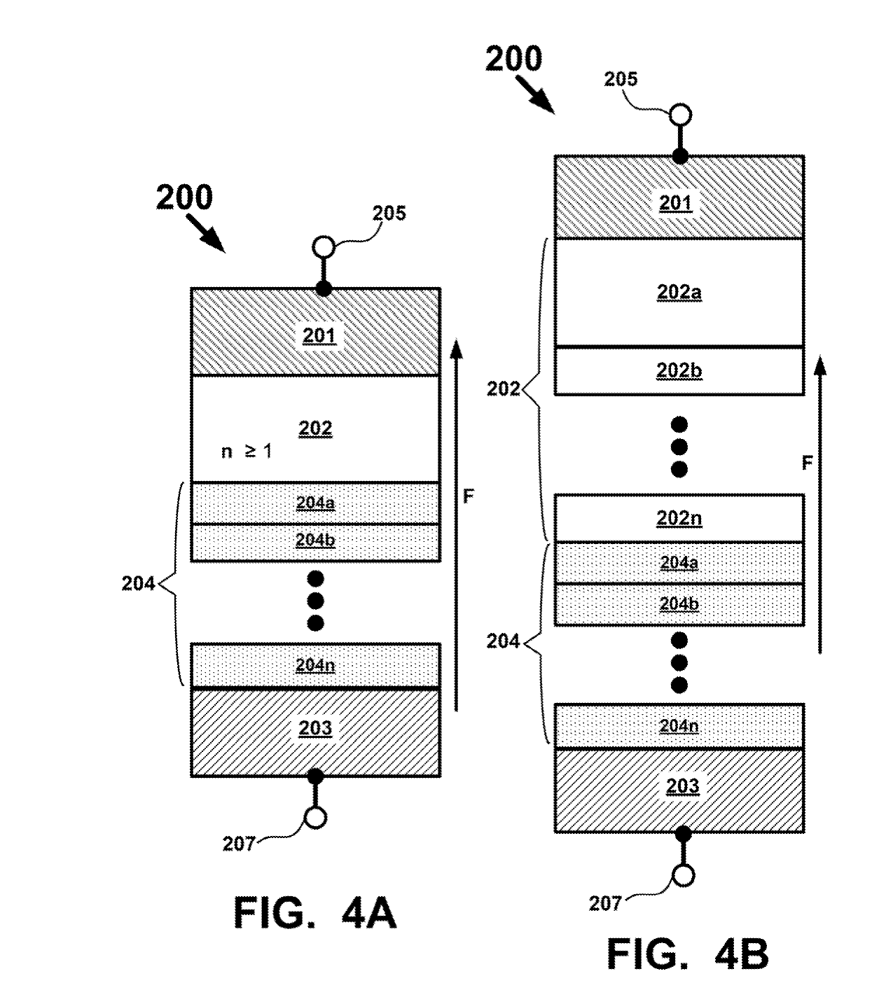

FIGS. 4A and 4B are similar to FIGS. 3A and 3B except the ME 200 has the CMO and IMO layers formed in a different fabrication order F (e.g., an inverted ME 200). Here, in FIG. 4A, distinct IMO layer 204a is in direct contact with CMO layer 202, distinct IMO layer 204b is in direct contact with IMO layer 204a, and the “” up to layer 204n is intended to make it clear that the ME 200 can include a third, a fourth, a fifth, up to an Nth IMO layer. As stated above, the minimum number of IMO layers is two (N≧2); therefore ME 200 would at least have IMO layers 204a and 204b. In FIG. 4B, there are at least two distinct layers of CMO denoted as 202a, 202b, up to an nth layer 202n. Therefore, the example of FIG. 4B illustrates at least two distinct layers of CMO with the distinct IMO layer 204a in direct contact with the last of the CMO layers (e.g., layer 202n).

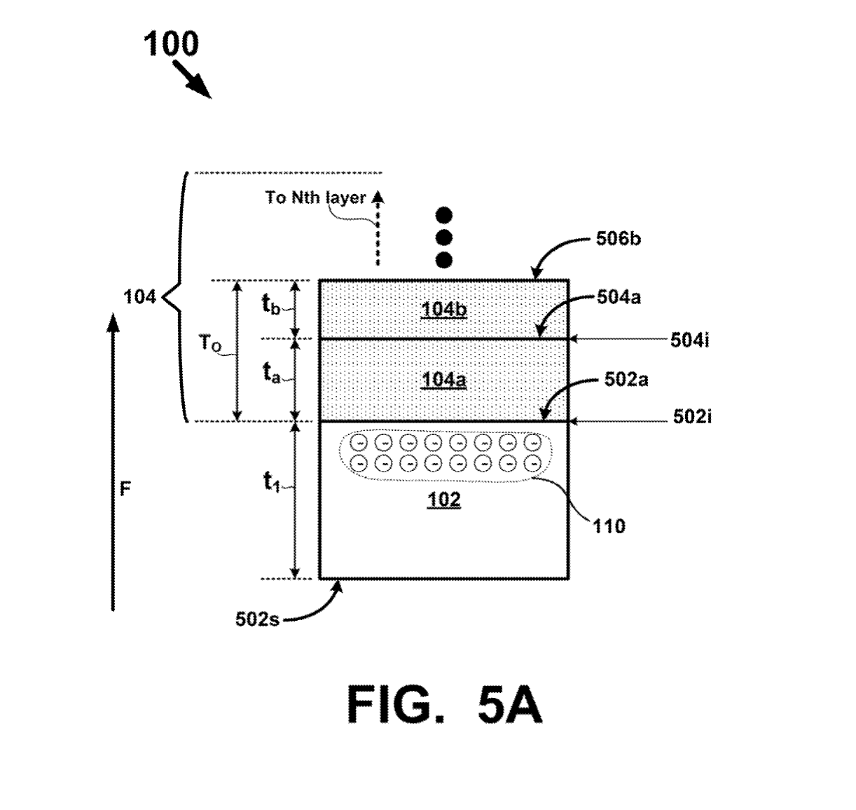

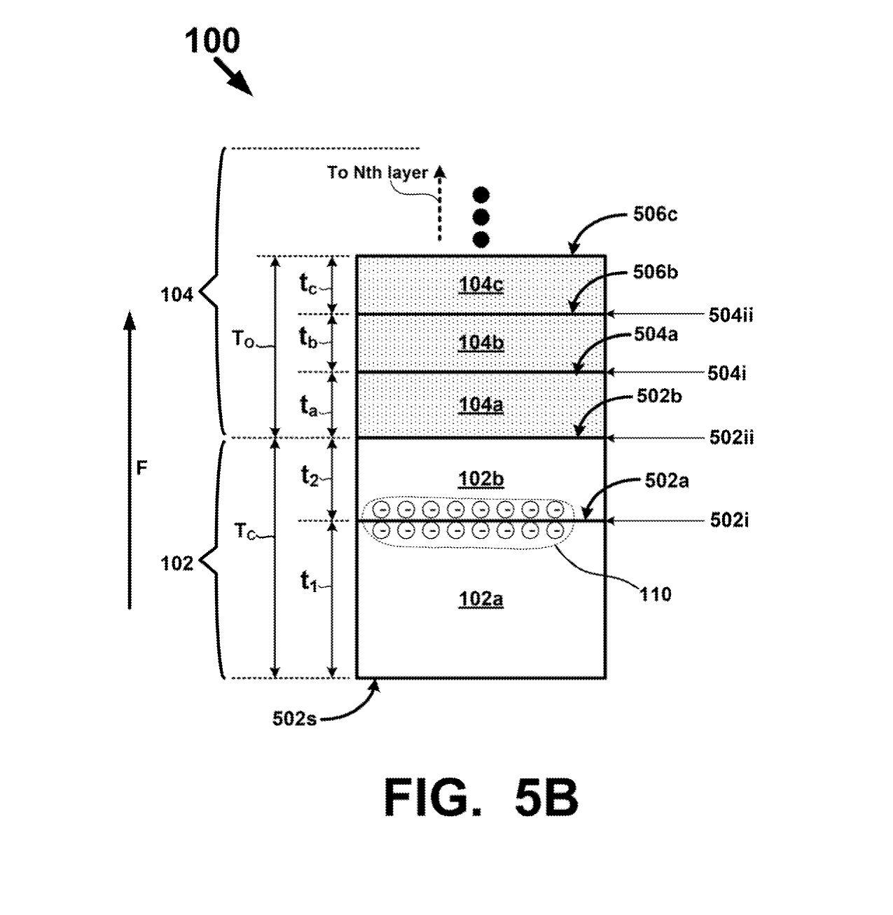

Turning now to FIG. 5A, a cross-sectional view depicts a layer of CMO 102 and a minimum of two distinct layers of IMO 104a, 104b, up to a Nth layer (not shown) that are in direct contact with one another. CMO layer 102 has a thickness t₁. If there are additional layers of CMO, then each layer will have an individual thickness as will be described below in FIG. 5B. Each IMO layer has its own individual layer thickness denoted as thicknesses tₐ and t_{b} for layers 104a and 104b respectively. A combined thickness of all of the IMO layers T_{O} is approximately the sum of all the individual layer thicknesses (e.g., T_{O}≈tₐ+t_{b}). Preferably, T_{O} is approximately 50 Angstroms or less. More preferably, T_{O} is approximately 40 Angstroms or less. For example, in some application T_{O} is approximately 35 Angstroms or less. Preferably, each layer of ME 100 has a uniform thickness and a substantially planar upper surface. Here, upper surfaces 502a, 504a, and 506b are preferably smooth and planar. Smooth and planar surfaces provide for uniformity of layer thickness and provide for consistent current densities through IMO layers 104a and 104b when voltages for data operations are applied across the ME 100 (e.g., applied to electrodes 101 and 103). Each layer of ME 100 forms an interface with an adjacent layer as denoted by interfaces 502i and 504i. First electrode structure 101 (not shown) can be in direct contact with a surface 502s of the CMO 102 and sans any additional IMO layers, the second electrode structure 103 (not shown) can be in direct contact with a surface 506b of IMO layer 104b.

Referring now to FIG. 5B, a cross-sectional view depicts a ME 100 having two CMO layers 102a and 102b and at least three IMO layers 104a, 104b, 104c, and up to a Nth layer (not shown). Each CMO layer has its own individual layer thickness t₁ and t₂ for layers 102a and 102b respectively and a combined thickness of all of the CMO layers T_{C} is approximately the sum of all the individual layer thicknesses (e.g., T_{C}≈t₁+t₂). Each IMO layer has its own individual layer thickness denoted as thicknesses tₐ, t_{b} and t_{c} for layers 104a, 104b and 104c respectively. A combined thickness of all of the IMO layers T_{O} is approximately the sum of all the individual layer thicknesses (e.g., T_{O}=tₐ+t_{b}+t_{c}). Here, several interfaces between adjacent layers are formed and are denoted as 502i, 502ii, 504i, and 504ii. As mentioned above, it is desirable for each layer to have a uniform thickness and a substantially smooth and planar upper surface. Here upper surfaces are denoted as 502a, 502b, 504a, 506b, and 506c. First electrode structure 101 (not shown) can be in direct contact with a surface 502s of the CMO 102a and sans any additional IMO layers, the second electrode structure 103 (not shown) can be in direct contact with a surface 506c of IMO layer 104c.

In FIG. 5B, the mobile oxygen ions 110 may be distributed between both of the CMO layers 102a and 102b as depicted, or one of the layers may have all or a substantial portion of the mobile oxygen ions 110. In FIG. 5A, the mobile oxygen ions 110 in the ME 100 may be positioned in the CMO 102 until data operations transport at least a portion of the mobile oxygen ions 110 into or out of one or more of the IMO layers (104a, 104b). As will be described below, the actual position of the mobile oxygen ions 110 in the ME 100 will be application specific and may depend on the write history of the ME 100 and/or the current state of data stored in the ME 100 (e.g., programmed or erased state, or value of data stored in the ME 100).

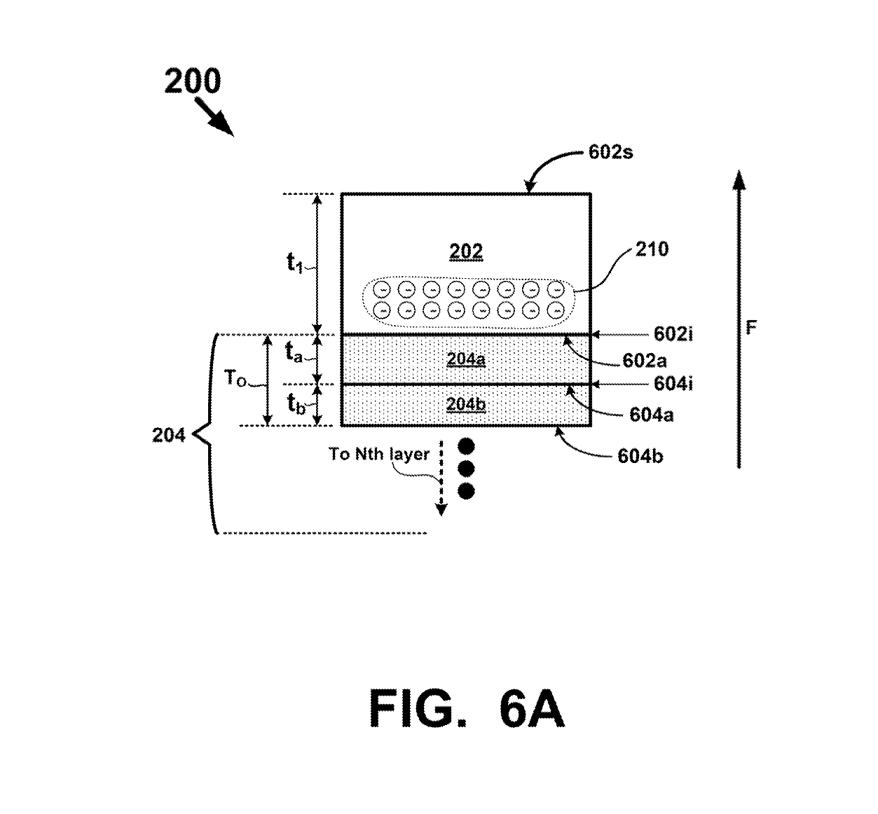

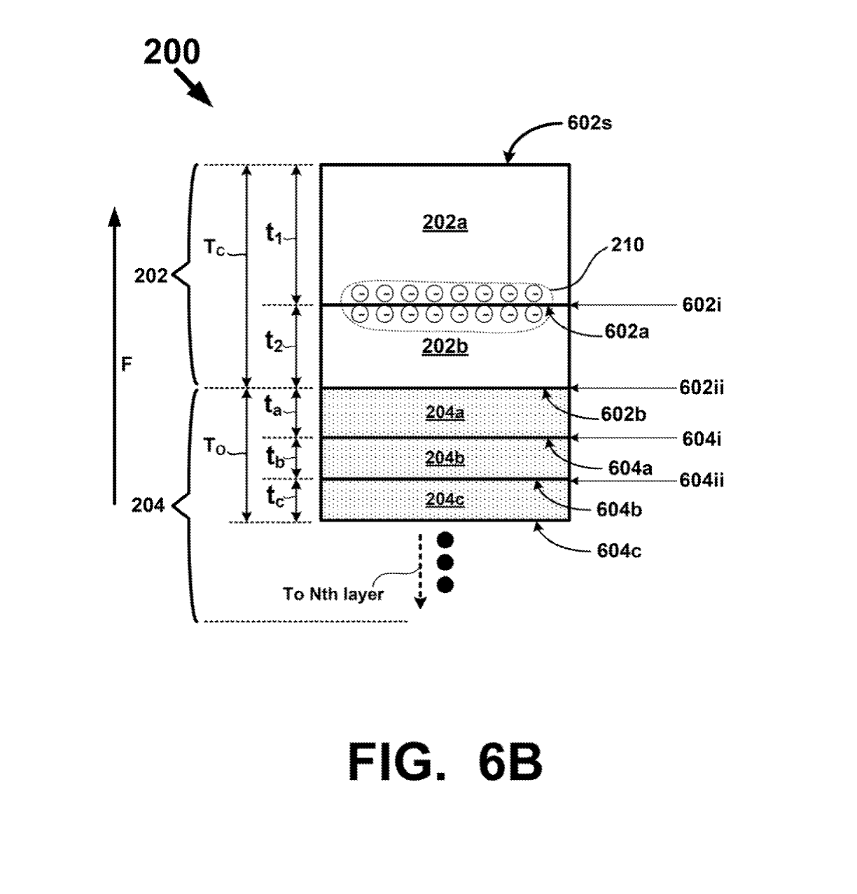

FIGS. 6A and 6B are similar to FIGS. 5A and 5B with the exception that the IMO layers 204a-204c are formed first in the fabrication order F followed by the CMO layers 202 or 202b-202a. The individual layer thicknesses, interfaces between adjacent layers, and upper surfaces described above in regards to FIGS. 5A and 5B also apply to the configurations depicted in FIGS. 6A and 6B. In FIGS. 5B and 6B, when multiple CMO layers are used, the individual layer thicknesses can vary such that one layer can be substantially thinner or thicker than an adjacent layer or some other layer. For example, t₂ can be much thinner than t₁.

In FIGS. 3A-6B, the IMO layers depicted (e.g., at least two layers such as 104, 204, 104a-104n, 204a-204n) can include at least one pair of adjacent IMO layers that are made from different IMO materials. In one example, at least one of the plurality of N distinct IMO layers is made from a different IMO material or an IMO material having a different stoichiometry. In some embodiments, the difference between the materials for the adjacent IMO layers can be a difference in stoichiometry. In other embodiments, the adjacent IMO layers can be made from IMO materials that are specifically selected to be non-reactive with each other. In yet another embodiment, the N distinct layers of IMO can include at least two IMO layers that have different band gaps. In some examples, the IMO layers that have different band gaps can be adjacent IMO layers. For example, the difference in band gap voltage between the IMO layers having different band gaps can be approximately 1.0 eV or more. As another example, the IMO layers having different band gaps can comprise a layer having a first band gap that is greater than or equal about 5.0 eV and another layer having a second band gap that is less than or equal to about 3.0 eV. In one example, the layer comprises the first layer of IMO that is in direct contact with the CMO layer 102 (i.e., in contact with the uppermost layer of the at least one layer of CMO 102). In a second example, the another layer comprises the first layer. In third example, the layer and the another layer are adjacent IMO layers. Actual values for the band gaps for the layers of IMO will be application dependent and may depend on factors such as the IMO materials selected for each IMO layer, just to name a few. In one example, the first layer (e.g., 104a) and an adjacent IMO layer comprise different IMO materials that include but are not limited to a high-k dielectric material, cerium oxide, and gadolinium doped cerium oxide.

In FIGS. 3A-6B, the CMO layers depicted (e.g., 102, 202, 102a-102n, 202a-202n) two or more of the plurality of distinct CMO layers can be made from different CMO materials and/or from CMO materials having different stoichiometry. As described above, when multiple CMO layers are used, the CMO layers can have individual layer thicknesses that vary. In some examples, the first layer of IMO is in direct contact with the thinnest layer of the plurality of CMO layers.

The individual layer thicknesses for each distinct IMO layer preferably does not vary by more than approximately 5.0 Angstroms for that layer. More preferably, the individual layer thicknesses for each distinct IMO layer does not vary by more than 3.0 Angstroms for that layer. In some examples, there will be a plurality of ME's (e.g., ME 100 and/or ME 200) such as in a cross-point array configuration, or other configuration. Preferably, the individual layer thickness for each of the N distinct layers of IMO does not vary in thickness by more than approximately 5.0 Angstroms among the plurality of ME's. More preferably, the individual layer thickness for each of the N distinct layers of IMO does not vary in thickness by more than approximately 3.0 Angstroms among the plurality of ME's. The plurality of ME's may be positioned on the same die of a silicon substrate, such as a silicon die or wafer, for example. The variation tolerance for the individual layer thickness can be for ME's within the same die or for ME's on the same wafer.

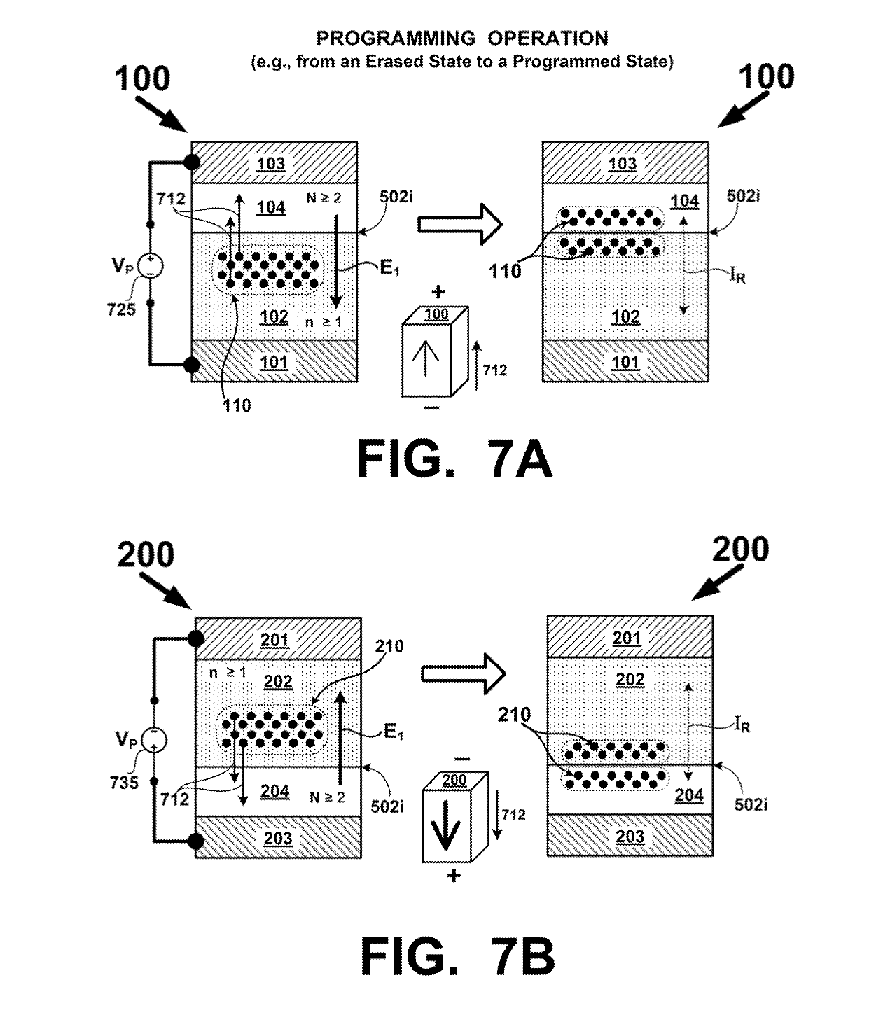

FIGS. 7A and 7B depict one example of a type of write operation to ME 100 and ME 200 respectively. In FIG. 7A for non-inverted ME 100, a programming operation comprises application of a programming voltage V_{P} from voltage source 725 to first and second electrode structures 101 and 103. Application of the programming voltage V_{P} generates an electric field E₁ that is operative to transport 712 at least a portion of the mobile oxygen ions 110 from the one or more layers of CMO 102 pass the interface 502i and into the layers of IMO 104. Here, the mobile oxygen ions 110 are transported 712 in a direction that is opposite that of the electric field E₁. After the programming voltage V_{P} is disconnected, the mobile ions 110 that were transported remain in the layers of IMO 104. In FIG. 7B, application of the programming voltage V_{P} from voltage source 735 to first and second electrode structures 201 and 203 generates electric field E₁ that is operative to transport 712 at least a portion of the mobile oxygen ions 210 from the one or more layers of CMO 202 pass the interface 502i and into the layers of IMO 204. Here, the direction of E₁ and direction of transport 712 are opposite that of FIG. 7A. After the programming voltage V_{P} is disconnected, the mobile ions 10 that were transported remain in the layers of IMO 204. A conductivity profile of the ME 100 and ME 200 is changed by the programming operation such that a resistance of the ME is changed (e.g., a programmed state) and non-volatile data is stored in the ME and is retained in the absence of electrical power. The value of data stored can be non-destructively determined by applying a read voltage (not shown) across the first and second electrode structures. Application of the read voltage generates a read current I_{R}. A magnitude of the read current I_{R} is indicative of the value of the data stored in the ME and can be sensed by circuitry that can output a data value (e.g., a logic “0” or “1” for SLC, or “00”, “01”, “10”, or “11” for MLC) based on the magnitude of the read current I_{R}.

FIGS. 8A and 8B depict one example of a type of write operation to ME 100 and ME 200 respectively. In FIG. 8A for non-inverted ME 100, an erase operation comprises application of an erase voltage V_{E} from voltage source 825 to first and second electrode structures 101 and 103. Application of the erase voltage V_{E} generates an electric field E₂ that is operative to transport 712 all or substantially all of the mobile oxygen ions 110 from the layers of IMO 104 pass the interface 502i and into one or more layers of CMO 102. As mentioned above, the mobile oxygen ions 110 are transported 712 in a direction that is opposite that of the electric field E₂. After the erase voltage V_{E} is removed the mobile oxygen ions 110 that were transported 712 remain in the one or more layers of CMO 102. The erase operation changes the conductivity profile of the ME 100 such a resistance of the ME 100 is changed and non-volatile data (e.g., an erased state) is stored in the ME 100 and is retained in the absence of electrical power. FIG. 8B is similar to FIG. 8A except the directions of electric field E₂ and transport 712 are opposite that of FIG. 8A. As mentioned above, the application of a read voltage will generate read current I_{R} that is indicative of the value of the data stored in the ME (100 or 200) and can be sensed by circuitry that can output a data value (e.g., a logic “0” or “1” for SLC, or “00”, “01”, “10”, or “11” for MLC) based on the magnitude of the read current I_{R}.

Actual values for the resistive state, their associated logic values, and the designation of those states (e.g., programmed, erased, etc.) will be application dependent. For example, the programmed state depicted in FIGS. 7A and 7B can be a high resistance state that represents a logic “0” whereas the erased state depicted in FIGS. 8A and 8B can be a low resistance state that represents a logic “1”. For the same magnitude of read voltage, the read current I_{R} will be lower when the ME (100 or 200) stores data in the programmed state than when the when the ME (100 or 200) stores data in the erased state due to the higher resistance of the programmed state. In some applications, the ME (100 or 200) stores one-bit of non-volatile data (SLC) and in other applications the ME (100 or 200) stores at least two-bits of data (MLC).

FIG. 9 depicts a profile view of a multi-layer vertical two-terminal cross-point memory array 900. Array 900 includes non-inverted ME 100 in even memory layers 0 and 2 and inverted ME 200 in odd memory layers 1 and 3. Although four layers are depicted, array 900 can include additional memory layers up to memory layer N. The structure depicted in FIG. 9 can be fabricated entirely BEOL along a +Z axis and can be accessed for data operation using FEOL circuitry (not shown) along a −Z axis. Each ME is positioned between a cross-point of a unique pair of word lines and bit lines (e.g., a unique pair of conductive array lines) and is directly electrically in series with its respective pair of word and bit lines. Here, word lines are denoted as X0-1-X0-3 and X1-1-X1-3; whereas bit lines are denoted as Y0-1-Y0-3, Y1-1-Y1-3, and Y2-1-Y2-3. Here, each ME electrically shares a word line, a bit line, or both with a ME in an adjacent memory layer. One advantage to configuring array 900 with inverted 200 and non-inverted 100 ME's is that disturb effects of half-select voltages on ME's that are not selected for a data operation can be minimized as described in U.S. patent application Ser. No. 13/171,350, filed on Jun. 28, 2011, and titled “Multilayer Cross-Point Memory Array Having Reduced Disturb Susceptibility”, already incorporated by reference.

In some embodiments, an array, such as a two-terminal cross-point array can be configured with only ME's 100 or only ME's 200 and the present invention is not limited to the configuration depicted in FIG. 9. Furthermore, the ME's 100 and/or 200 depicted herein need not be configured in an array or cross-point array configuration and may be implemented in any number of various configurations that require non-volatile memory, including as a single ME or a plurality of ME's such as in a memory cache, register or buffer, for example.

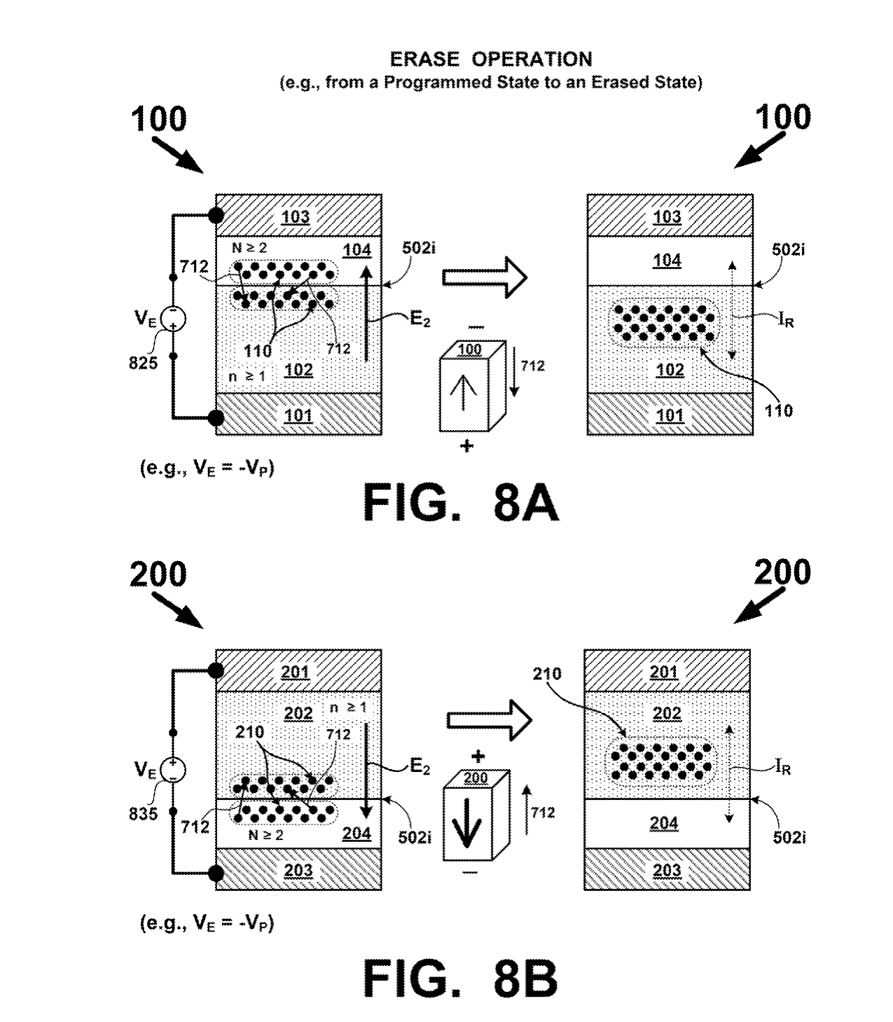

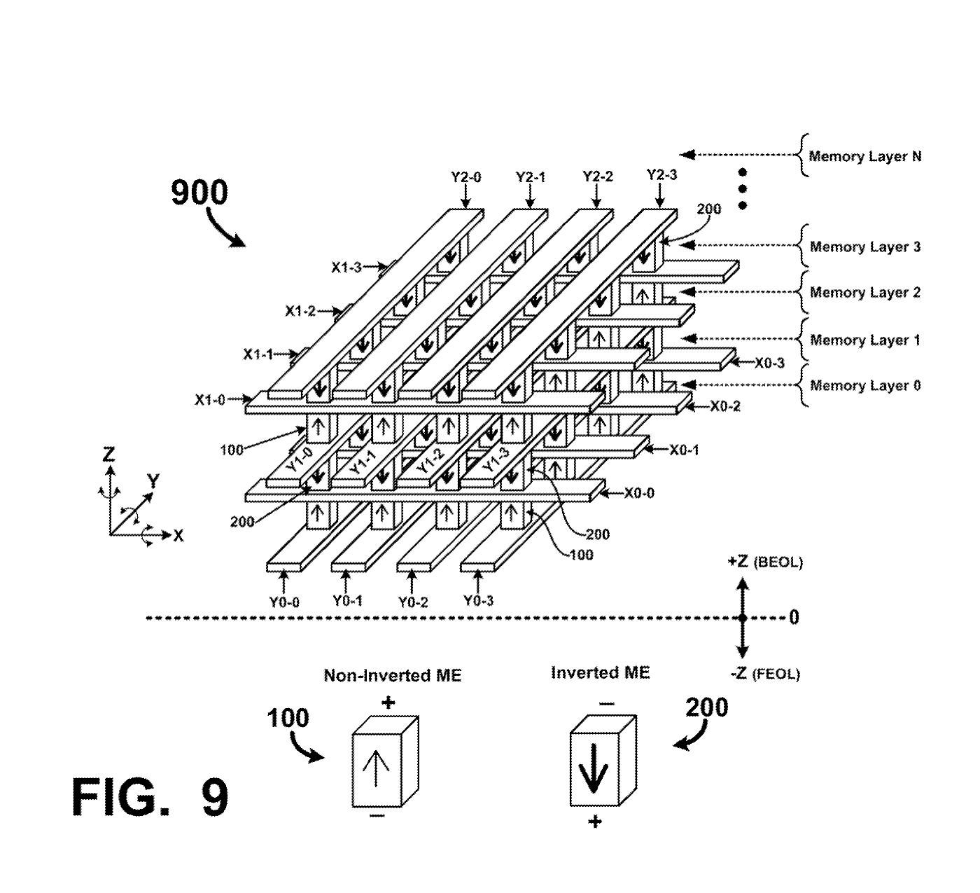

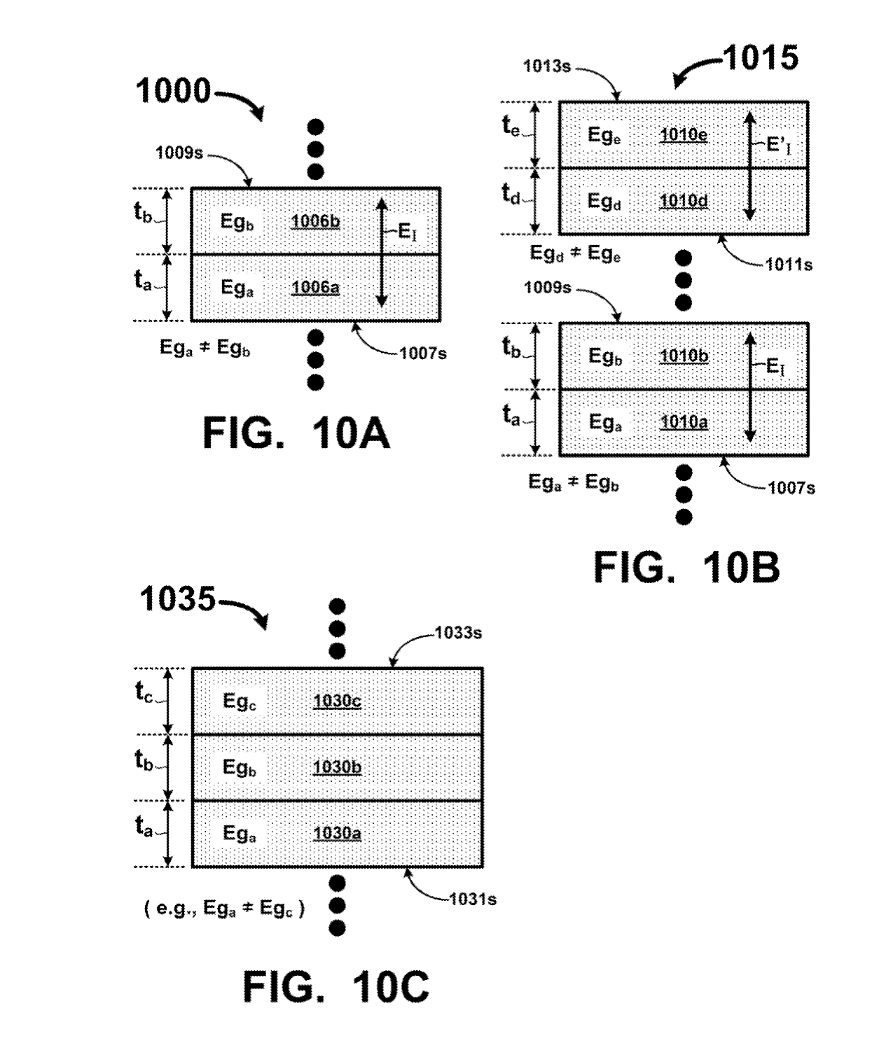

Reference is now made to FIGS. 10A-10C, where the IMO layers depicted therein can be the multiple IMO layers for the ME 100 or ME 200. In a configuration 1000 of FIG. 10A, adjacent IMO layers 1006a and 1006b are in direct contact with each other and have individual layer thicknesses tₐ and t_{b} respectively. Further, IMO layers 1006a and 1006b have different band gaps denoted as Egₐ and Eg_{b} respectively, where Egₐ≠Eg_{b}. IMO layers 1006a and 1006b may be made from different IMO materials and/or have different stoichiometry. In some embodiments, IMO layers 1006a and 1006b include an internal electric field E_{I} that is positioned in the IMO layers 1006a and 1006b and is present in the IMO layers 1006a and 1006b in the absence of electrical power (e.g., when no voltage is applied across the first and second electrode structures of the ME). Upper surfaces 1007s and 1009s may be in direct contact with either the uppermost CMO layer, the first or second electrode structures, or with another IMO layer. The magnitude and direction of the internal electric field E_{I} will be application dependent and may depend on factors including but not limited to the band gaps Egₐ and Eg_{b}, the materials for the IMO layers 1006a and 1006b, the layer thicknesses tₐ and t_{b}, just to name a few.

In some applications, the internal electric field E_{I} is operative to improve data retention of the ME (100, 200). Data retention is a measure of how long a data valued stored in the ME is retained without substantial degradation of the conductivity profile (e.g., a resistance value) of the data value (e.g., programmed state-high resistance or erased state-low resistance). Data retention can be measured in units of time such as minutes, day, weeks, months, years, etc., for example. As one example, in FIGS. 7A and 7B, when the ME stores data in the programmed state, the IMO layers 1006a and 1006b can be specifically configured to generate internal electric field E_{I} that points from the IMO layers towards the CMO layer 102 (i.e., points in the same direction as E₁) such that the portion of mobile oxygen ions (110, 210) that are positioned in the IMO layers 1006a and 1006b are retained in the IMO layers 1006a and 1006b and do not migrate or drift back into the CMO layer 102 because the direction of the internal electric field E_{I} is operative to act against the mobile oxygen ions 110 in a direction that is away from (i.e., opposite to the direction of E_{I}) the CMO layer 102.

Conversely, in FIGS. 8A and 8B, in another example, when the ME stores data in the erased state, the IMO layers 1006a and 1006b can be specifically configured to generate internal electric field E_{I} that points away from the CMO layer 102 (i.e., points in the same direction as E₂). Here, all or substantially all of the mobile oxygen ions (110, 210) that are positioned in the CMO 102 are retained in the CMO layer 102 and do not migrate or drift back into the IMO layers 104 because the direction of the internal electric field E_{I} is operative to act against the mobile oxygen ions 110 in a direction that is away from (i.e., opposite to the direction of E_{I}) the IMO layers 104. In either example, the internal electric field E_{I} can be tailored to prevent or minimize movement or drift of mobile oxygen ions (110, 210) when the ME (100, 200) is not being subjected to a write operation, such that value of data stored in the ME (100, 200) is not altered at all or substantially un-altered when the ME is not subject to data operations or during read operations.

FIG. 10B depicts another example of a ME (100, 200) in which there are at least two pair of adjacent IMO layers that have different band gaps. In configuration 1015, adjacent IMO layers 1010a and 1010b have different band gaps denoted as Egₐ and Eg_{b} respectively, where Egₐ≠Eg_{b} and include internal electric field E_{I}. Whereas, adjacent IMO layers 1010d and 1010e have different band gaps denoted as Eg_{d} and Egₑ respectively, where Eg_{d}≠Egₑ and include internal electric field E′_{I}. The magnitude and/or direction of internal electric fields E_{I} and E′_{I} need not be the same and as mentioned above, the of internal electric fields E_{I} and E′_{I} are positioned in their respective IMO layers in the absence of electrical power. In FIG. 10B, there may be additional IMO layers in contact with surfaces 1009s and 1011s and surfaces 1007s and 1013s may be in direct contact with either the uppermost CMO layer, the first or second electrode structures, or with another IMO layer.

In FIG. 10C, a configuration 1035 depicts three adjacent IMO layers 1030a, 1030b, and 1030c that are in direct contact with one another and each layer having a band gap denoted as Egₐ, Eg_{b} and Eg_{c}, respectively. In the example depicted at least two of the three layers has a band gap that is different (i.e., Egₐ≠Eg_{c}). Surfaces 1031s and 1033s may be in direct contact with either the uppermost CMO layer, the first or second electrode structures, or with another IMO layer. The difference in band gaps is not limited to the example depicted and layer 1030a can have a different band gap than layer 1030b or layer 1030b can have a different band gap than layer 1030c. Adjacent IMO layers in configuration 1035 that have different band gaps can be configured to generate the internal electric field (not shown) as described above.

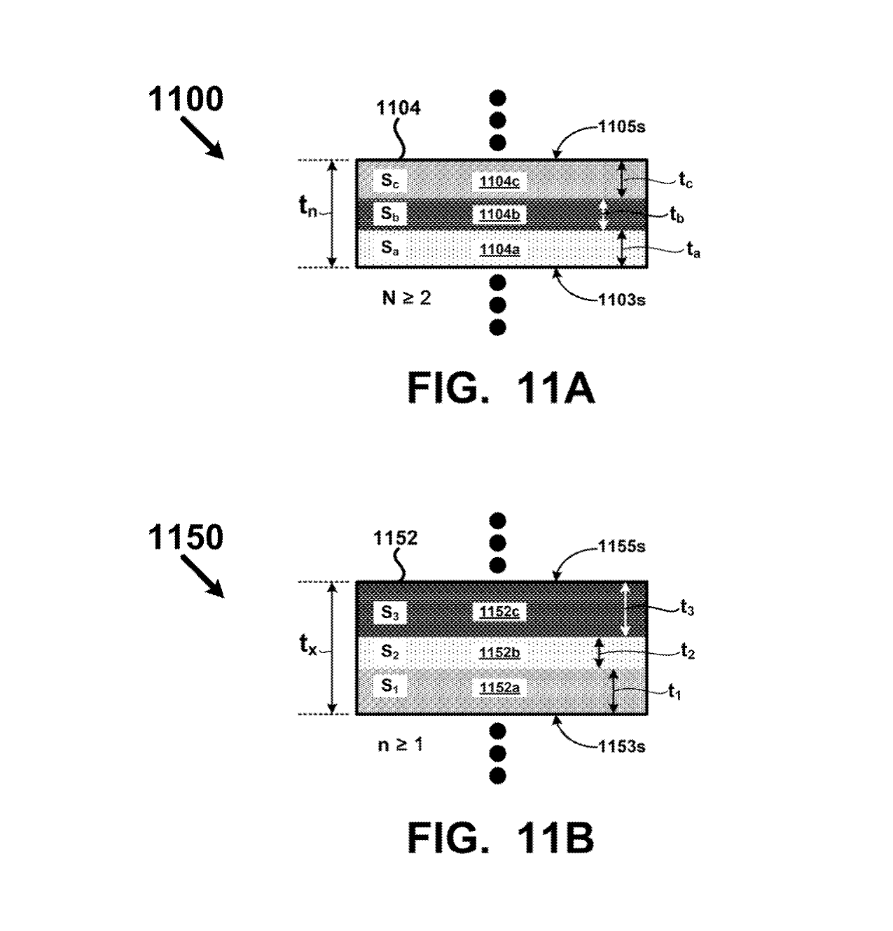

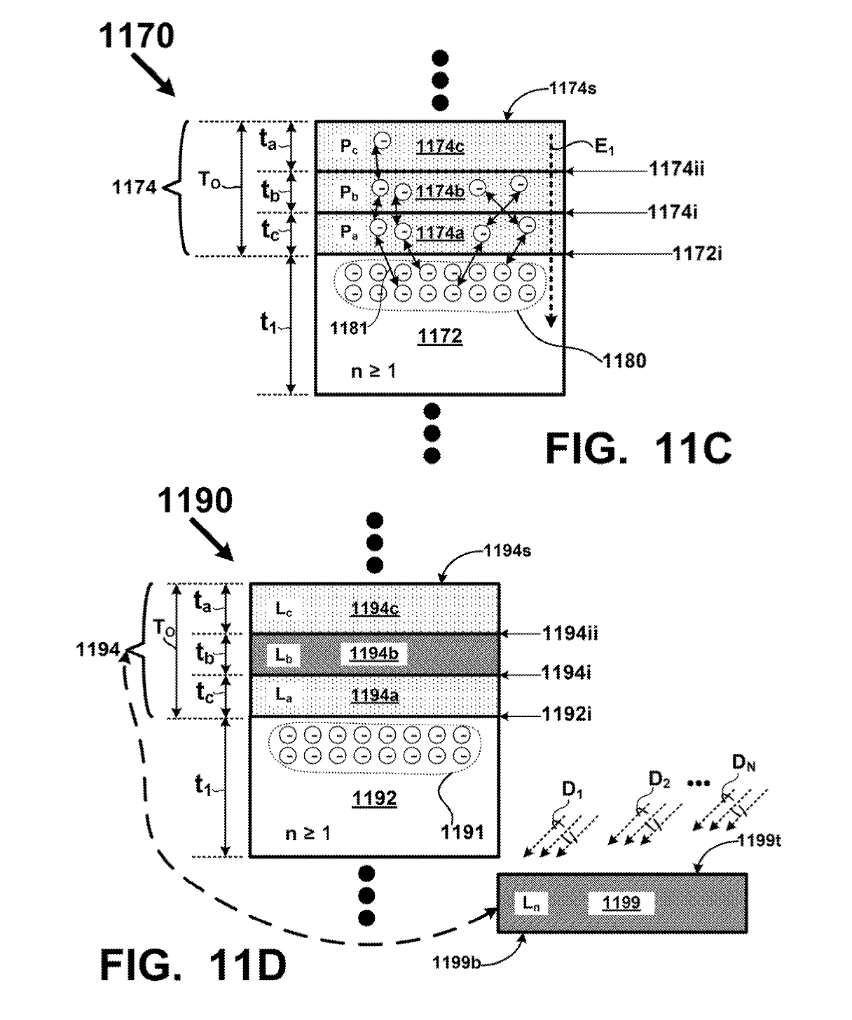

Now reference is made to FIG. 11A where a cross-sectional view depicts an example of a distinct layer of IMO 1104 having an individual layer thickness of tₙ and within that thickness tₙ the layer 1104 includes variations in stoichiometry denoted as Sₐ for sub-layer 1104a, S_{b} for sub-layer 1104b, and S_{c} for sub-layer 1104c, where each sub-layer has an approximate sub-layer thickness denoted as tₐ, t_{b}, and t_{c}. In that the ME (100, 200) includes at least two distinct layers of IMO (i.e., N≧2), configuration 1100 includes additional IMO layers (not shown) that can be positioned below surface 1103s or above surface 1105s. The number of actual sub-layers will be application dependent and more or fewer sub-layers can be included in IMO layer 1104. The differences in stoichiometry between the adjacent sub-layers can be use to tune the IMO layer for specific device related characteristics such as data retention, memory effect (i.e., the difference in magnitude between different resistive states), mobile oxygen ion (110, 210) mobility in the sub-layer(s) of layer 1104 during write operations, band gap, and electron tunneling characteristics, just to name a few.

Referring now to FIG. 11B, configuration 1150 depicts an example of a distinct layer of CMO 1152 having an individual layer thickness of t_{X} and within that thickness t_{X} the layer 1152 includes variations in stoichiometry denoted as S₁ for sub-layer 1152a, S₂ for sub-layer 1152b, and S₃ for sub-layer 1152c, where each sub-layer has an approximate sub-layer thickness denoted as t₁, t₂, and t₃. In that the ME (100, 200) includes at least one distinct layer of CMO (i.e., n≧1), configuration 1150 can include one or more additional CMO layers (not shown) that can be positioned below surface 1153s or above surface 1155s. The number of actual sub-layers will be application dependent and more or fewer sub-layers can be included in CMO layer 1152. The differences in stoichiometry between the adjacent sub-layers can be use to tune the CMO layer 1152 for specific device related characteristics such as data retention, memory effect (i.e., the difference in magnitude between different resistive states), mobile oxygen ion (110, 210) mobility in the sub-layer(s) of layer 1152 during write operations, mobile oxygen ion (110, 210) concentration within the sub-layer(s) of layer 1152, just to name a few. For example, the stoichiometry of sub-layer 1152c can be configured so that it has a higher concentration of mobile oxygen ion (110, 210) than sub-layers 1152a or 1152b. The higher concentration in sub-layer 1152c can be used to position the mobile oxygen ion (110, 210) closer to the interface (e.g., 502i, 502ii, 602i, 602ii) between the first layer of IMO and the layer 1152. Benefits of this configuration include reducing a distance the mobile oxygen ion (110, 210) travel when they are transported 712 between the CMO layer 1152 and the IMO layer(s) during write operations to the ME (100, 200).

Turning now to FIG. 11C, configuration 1170 depicts a cross-sectional view of three distinct and adjacent IMO layers 1174a-1174c with layer 1174a being the first layer that is in direct contact with CMO layer 1172. Interfaces 1172i, 1174i, and 1174ii are defined by the contact between adjacent layers. Each IMO layer has a permeability to mobile oxygen ions 1180 as denoted by Pₐ, P_{b}, and P_{c}. Layer 1174a is an electrolyte to the mobile oxygen ions 1180 and layers 1174b and/or 1174c may also be an electrolyte to the mobile oxygen ions 1180. Here, first layer 1174a has permeability Pₐ selected to insure that at least a portion of the mobile oxygen ions 1180 are transported 1181 into or out of layer 1174a during write operations to the ME (100, 200). However, permeability P_{b}, and/or P_{c} can be selected such that layers 1174b and/or 1174c are also an electrolyte and are permeable to the mobile oxygen ions 1180 during write operations. For example, Pₐ, P_{b}, and P_{c} can be selected such that Pₐ for layer 1174a has a high permeability to the ions 1180, P_{b} for layer 1174b has a lower permeability to the ions 1180 than layer 1174a, and P_{c} for layer 1174c has an even lower permeability to the ions 1180 than layers 1174a and 1174b. Therefore, during a programming operation, fewer of the mobile oxygen ions 1180 are transported through interface 1174ii and into layer 1174c than is the case for layers 1174a and 1174b. The lower permeability of layer 1174c can be used for various purposes that improve device performance such as preventing or reducing the number of ions 1180 in the layer 1174c so that fewer ions 1180 have an opportunity to escape from the ME (100, 200) through surface 1174s (e.g., into the electrode structure if layer 1174c is the last layer). As another example, lower permeability of a layer, such as layer 1174c, can be used to ensure that a majority of the mobile oxygen ions 1180 are positioned closer to the interface 1172i after a programming operation such that when an erase operation is performed on the ME (100, 200) the distance the mobile oxygen ions 1180 have to travel to re-enter the CMO is reduced. This can improve memory effect and/or reduce erase time latency. A reduced transport distance can also reduce programming time latency.

In FIG. 11D, a cross-sectional view of a configuration 1190 depicts a cross-sectional view of three distinct and adjacent IMO layers 1194a-1194c with layer 1194a being the first layer that is in direct contact with CMO layer 1192. Interfaces 1192i, 1194i, and 1194ii are defined by the contact between adjacent layers. At least one CMO layer 1192 includes mobile oxygen ions 1191 and at least the layer 1194a of the three IMO layers 1194 is an electrolyte and is permeable to the mobile oxygen ions 1191 during write operations. In configuration 1190 at least one of the IMO layers 1194 (Lₐ, L_{b}, and L_{c}) comprises a soft-blended multi-phase IMO layer. Here, for purposes of illustration, only the layer 1194b comprises a soft-blended multi-phase IMO layer; whereas, layers 1194a and 1194c comprise other types of IMO layers as described herein. Layer 1199 depicts one example of a soft-blended multi-phase IMO layer L_{N}. Here two or more deposition sources denoted as D₁, D₂, . . . D_{N} are used to form the layer 1199 by techniques including but not limited to co-sputtering, ALD, PEALD, CVD, PECVD, or other deposition techniques described herein, or the like. The term multi-phase means at least two different materials as will be described below. For example, layer 1199 can be formed by co-sputtering two different IMO materials at the same time, at substantially the same time, at alternating or varying time intervals, or any combination of the above. As one example a first IMO comprising yttrium stabilized zirconia (YSZ) can be deposition source D₁ and silicon oxide (SiOx) can be deposition source D₂. The combined deposition sources (D₁ and D₂) can form a soft-blended dual-phase IMO layer 1199. The layer 1199 can be formed from more than two sources and if three sources are used, then combined deposition sources (D₁, D₂ and D₃) can form a soft-blended triple-phase IMO layer 1199. The soft-blended multi-phase IMO layer 1199 can be implemented as one or more of the layers 1194 and is not limited to the configuration depicted. The soft-blended multi-phase IMO layer 1199 can be the first layer, the last layer, or one or more layers in between the first and last layers of IMO 1194. Surfaces 1199b and 1199t can be in contact with an adjacent IMO layer, the uppermost CMO layer, or one of the electrode structures. The soft-blended multi-phase IMO layer 1199 can be configured to provide a application specific permeability to the mobile oxygen ions 1191, to modify a band gap of the layer 1199, modify a stoichiometry of the layer 1199, modify an electron tunneling characteristic of the layer 1199, modify voltages for data operations, modify an I-V characteristic (linear or non-linear) of the memory element, just to name a few.

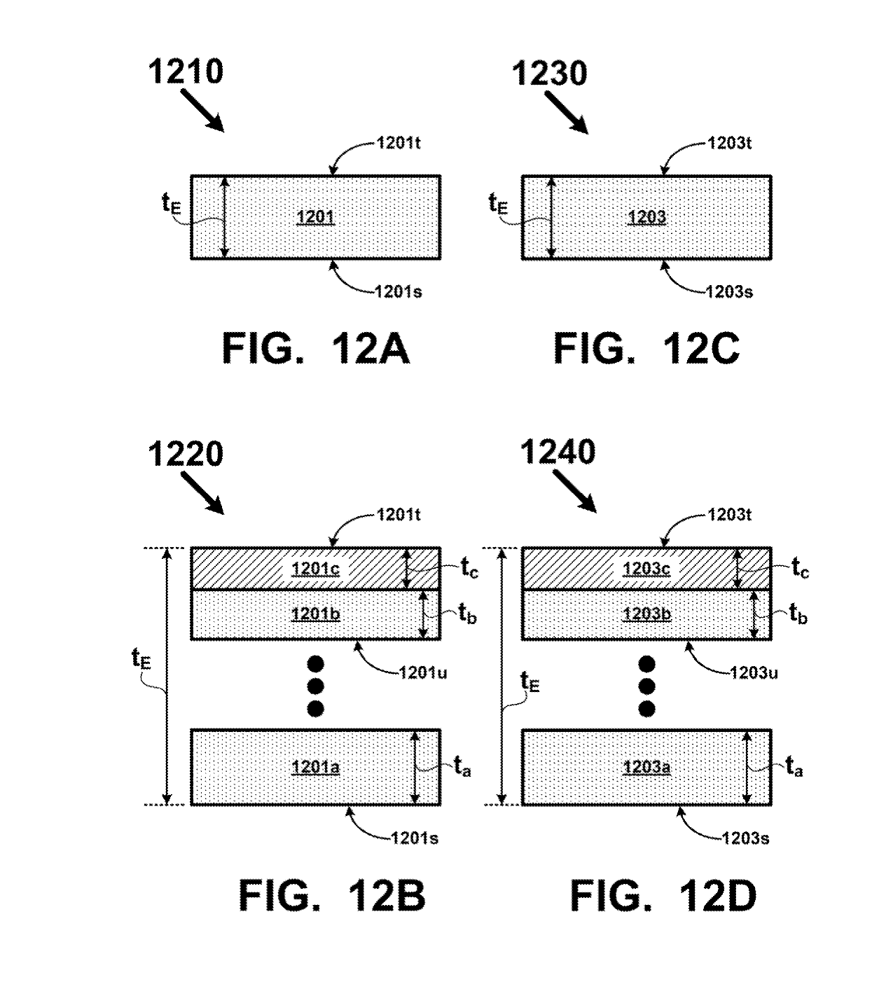

Moving on to FIGS. 12A and 12B, where two different examples of configurations 1210 and 1220 for the first electrode structure are depicted in cross-sectional views. In FIG. 12A the first electrode structure 1201 comprises a single layer of an electrically conductive material and has opposed surfaces 1201s and 1201t. Preferably, first electrode structure 1201 has a uniform thickness t_{E} such that the surfaces 1201s and 1201t are substantially planar and smooth, particularly the upper surface (e.g., 1201t) if additional thin-film layers (e.g., CMO and/or IMO) for the ME (100, 200) will be deposited on the upper surface so that the smooth and planer surface morphology will be replicated in subsequently deposited thin-film layers. Suitable electrically conductive materials for the first electrode structure 1201 include but are not limited to metals, metal alloys, a non-reactive metal (e.g., platinum—Pt or ruthenium—Ru), an alloy of a non-reactive metal, a conductive metal oxide, iridium—Ir, iridium oxide—IrOx, just to name a few.

In FIG. 12B, configuration 1220 depicts a first electrode structure comprised of a plurality of layers of electrically conductive material instead of the single layer of electrically conductive material of configuration 1210 in FIG. 12A. Here, three layers are depicted, but configuration 1220 can include only two layers or more layers than depicted. The plurality of layers of electrically conductive material can include but are not limited to glue layers, adhesion layers, anti-reflection layers, an electrically conductive support layer, just to name a few. Here, all of the layers 1201a-1201c have a combined thickness t_{E} based on individual layer thicknesses tₐ, t_{b}, and t_{c}. Preferably, surfaces 1201s, 1201t and 1201u are substantially planar and smooth such that thickness t_{E} is substantially uniform. The same electrically conductive materials described above in regards to FIG. 12A can be used in the first electrode structure of configuration 1220. Examples of electrode structures that include a support layer are described in pending U.S. patent application Ser. No. 13/210,342, Filed Aug. 15, 2011, and titled “Structures And Methods For Facilitating Enhanced Cycling Endurance Of Memory Accesses To Re-Writable Non-Volatile Two-Terminal Memory Elements”, already incorporated herein by reference.

Configurations 1230 and 1240 of FIGS. 12C and 12D are similar to those of FIGS. 12A and 12B with the exception that FIGS. 12C and 12D show single layer and multi-layer configurations for the second electrode structure. The electrically conductive materials, combined and individual thicknesses, and other attributes described above in reference to FIGS. 12A and 12B may also apply to configurations 1230 and 1240 of FIGS. 12C and 12D.

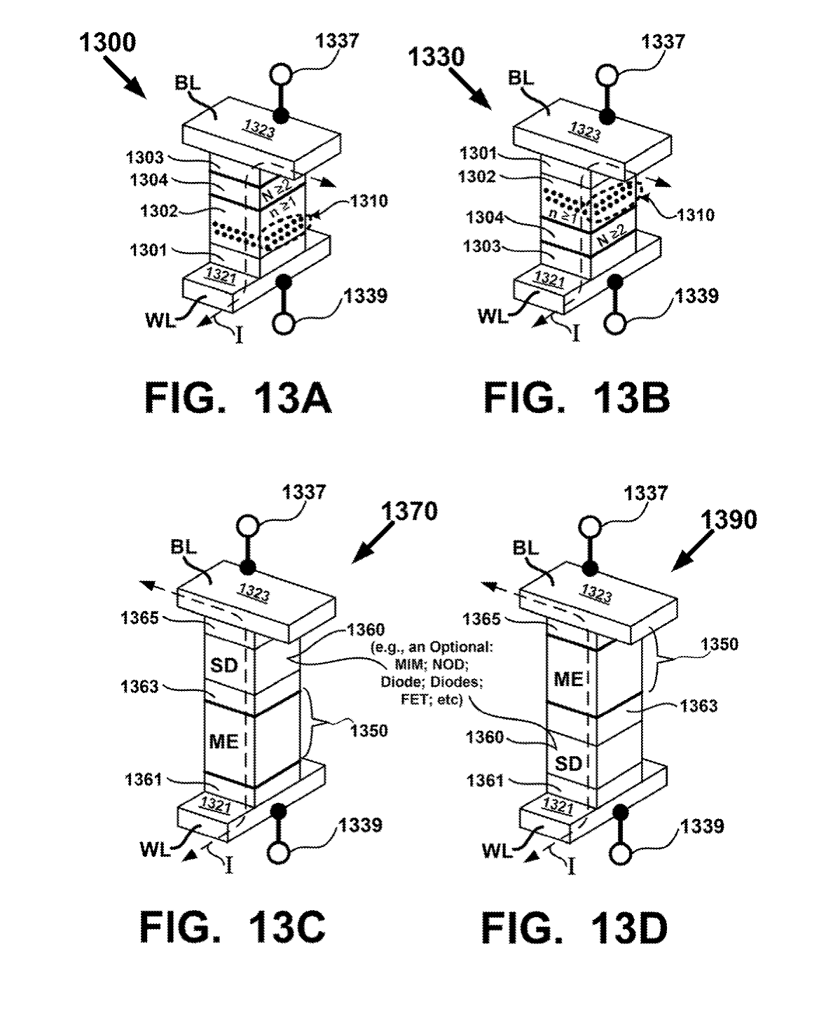

Referring now to FIGS. 13a and 13B, FIG. 13A depicts a profile cross-sectional view of a configuration 1300 for a non-inverted discrete two-terminal memory element positioned between a cross-point of two conductive array lines 1323 and 1321 (e.g., a bit line—BL and a word line—WL). Here nodes 1337 and 1339 electrically couple the WL and BL with circuitry operative to perform data operations on the memory element (e.g., FEOL circuitry). First electrode structure 1301 may be directly or indirectly electrically coupled with conductive array line 1321, CMO layer 1302 includes mobile oxygen ions 1310 and is in direct contact with electrode 1301, the first IMO layer of the plurality of IMO layers 1304 is in direct contact with CMO layer 1302, the last layer of the plurality of IMO layers 1304 is in direct contact with second electrode structure 1301, which in turn may be may be directly or indirectly electrically coupled with conductive array line 1323. Here, the two-terminal memory element is a discrete two-terminal memory element because there are no other structures, such as a selection device (SD), that is electrically in series between the first and second electrode structures (1301, 1303) or the conductive array lines (1321, 1323).

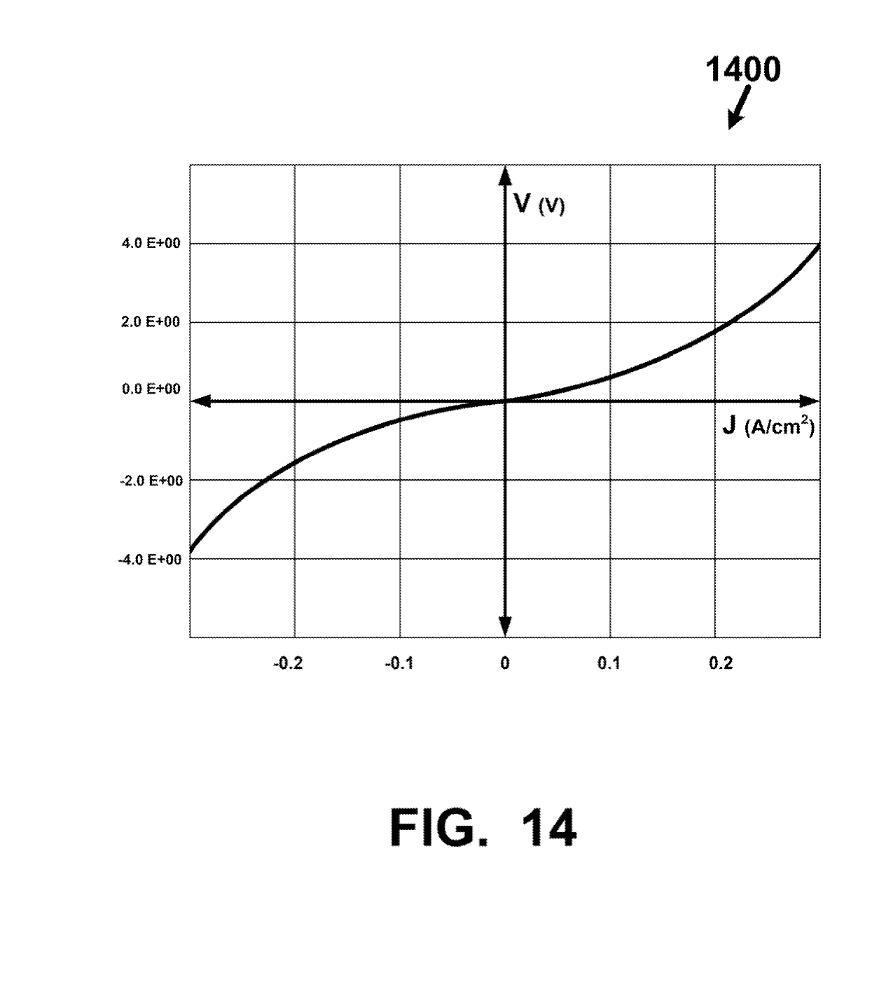

FIG. 13B depicts a similar configuration 1330 for an inverted discrete two-terminal memory element positioned between a cross-point of two conductive array lines 1323 and 1321 (e.g., a bit line—BL and a word line—WL). In FIGS. 13a and 13B a current I flows through the memory elements (100, 200) during data operations (e.g., a read operation). However, current I may not flow for all values of voltage potentials applied to nodes 1337 and 1339 because the memory elements (100, 200) can include a non-linear I-V characteristic as depicted in FIG. 14 and will be described in greater detail below.

FIGS. 13C and 13D depict profile cross-sectional views of two different examples of a memory element 1350 (ME) positioned between a cross-point of two conductive array lines and including an optional selection device 1360 (SD) positioned above the ME 1350 (FIG. 13C) or positioned below the ME 1350 (FIG. 13D). Here, the CMO and IMO layers of the ME 1350 are not depicted. In some embodiments, an intermediate electrode structure 1363 or other electrically conductive structure may be used to integrate the SD 1360 and ME 1350 with each other. In some applications, intermediate electrode structure 1363 can be the first or second electrode structure as described above. Electrode structures 1365 and 1361 may also be the first or second electrode structure as described above depending on the position of the ME 1350. For example, in FIG. 13C, electrode structure 1361 can be the first electrode structure and in FIG. 13D electrode structure 1365 can be the second electrode structure.

Selection device SD 1360 can be formed from a variety of electrical devices including but not limited to a non-ohmic device (NOD), one or more diodes, one or more transistors, and a metal-insulator-metal (MIM) device. SD 1360 can have its own I-V characteristic either linear or non-linear and is operative to block all or substantially all current I for specific ranges of applied voltages on node 1337, node 1339, or both. For example, current I may zero or substantially zero for all applied voltages that are not data operations voltages (e.g., read or write voltages), such as half-select voltages or other voltages that may appear on nodes 1337, 1339, or both when a ME 1350 is un-selected or otherwise not selected for a data operation. Here, SD 1360 is electrically in series with the ME 1350 and the conductive array lines 1321 and 1323. In some applications where the SD 1360 comprises a transistor (e.g., a FET), the ME 1350 remains a two-terminal device; however, a third node (e.g., a gate node of the FET) makes the overall data storage device (e.g., memory cell) a three-terminal device with the ME 1350 electrically in series with the source and drain nodes of the FET and the gate node comprises the third terminal.

FIG. 14 graphically depicts one example of a non-linear I-V characteristic 1400 for a discrete re-writeable non-volatile two-terminal resistive memory element (e.g., memory element 100, 200) having integral selectivity due to its non-linear I-V characteristics and the non-linear I-V characteristic is maintained regardless of the value of the data stored in the memory cell, that is the I-V characteristic of the memory element does not change from non-linear to linear as a function of the resistive state stored in the memory element. Therefore, the non-linear I-V characteristic of the memory element is non-linear for all values of stored data (e.g., resistive states). Voltage V applied across the memory element is plotted on the Y-axis and current density J through the memory element is plotted on the X-axis. Here, current through the memory element is a non-linear function of the applied voltage across the memory element. Accordingly, when voltages for data operations (e.g., read and write voltages) are applied across the memory element, current flow through the memory element does not significantly increase until after a voltage magnitude of about 2.0V (e.g., at ≈0.2 A/cm²) is reached (e.g., a read voltage of about 2.0V across the memory element). An approximate doubling of the voltage magnitude to about 4.0V does not double the current flow and results in a current flow of ≈0.3 A/cm². The graph depicted is only an example and actual non-linear I-V characteristics will be application dependent and will depend on factors including but not limited to an area of the memory element (e.g., area determines the current density J) and the thin-film materials used in the memory element, just to name a few. The area of the memory element will be application dependent. Here, the non-linear I-V characteristic of the discrete memory element applies to both positive and negative values of applied voltage as depicted by the non-linear I-V curves in the two quadrants of the non-linear I-V characteristic 1400. One advantage of a discrete re-writeable non-volatile two-terminal resistive memory element that has integral selectivity due to a non-linear I-V characteristic is that when the memory element is half-selected (e.g., one-half of the magnitude of a read voltage or a write voltage is applied across the memory element) during a data operation to a selected memory cell(s), the non-linear I-V characteristic is operative as an integral quasi-selection device and current flow through the memory element is reduced compared to a memory cell with a linear I-V characteristic. Therefore, a non-linear I-V characteristic can reduce data disturbs to the value of the resistive state stored in the memory element when the memory element is un-selected or is half-selected. In other embodiments, the memory element (e.g., memory element 100, 200) has a non-linear I-V characteristic for some values of the resistive state stored in the memory element and a linear I-V characteristic for other values of the resistive state stored in the memory element.

Materials for the ME

In various embodiments, the multiple IMO layers (e.g., N≧2) can include but are not limited to a material for implementing a tunnel barrier layer and where at least one of the IMO layers is also an electrolyte that is permeable to the mobile oxygen ions 1105 at voltages for write operations. Suitable materials for multiple IMO layers include but are not limited to one or more of the following: high-k dielectric materials, rare earth oxides, rare earth metal oxides, yttria-stabilized zirconium (YSZ), zirconia (ZrO_{X}), zirconium oxygen nitride (ZrOxNy), yttrium oxide (YO_{X}), erbium oxide (ErO_{X}), gadolinium oxide (GdO_{X}), lanthanum aluminum oxide (LaAIO_{X}), hafnium oxide (HfO_{X}), aluminum oxide (AlOx), silicon oxide (SiOx), cerium oxide (CeO_{X}), gadolinium doped cerium oxide (CeO_{X}), titanium oxide (TiOx), tantalum oxide (TaOx), and equivalent materials.

In various embodiments, the one or more CMO layers (e.g., n≧1) can include one or more layers of a conductive metal oxide material, such as one or more layers of a conductive metal oxide-based (“CMO-based”) material, for example. The CMO material is selected for it properties as a variable resistive material that includes mobile oxygen ions (110, 210) and is not selected based on any ferroelectric properties, piezoelectric properties, magnetic properties, superconductive properties, or for any mobile metal ion properties. In various embodiments, the one or more CMO layers can include but is not limited to a manganite material, a perovskite material selected from one or more the following: PrCaMnO_{X} (PCMO), LaNiO_{X} (LNO), SrRuO_{X} (SRO), LaSrCrO_{X} (LSCrO), LaCaMnO_{X} (LCMO), LaSrCaMnO_{X} (LSCMO), LaSrMnO_{X} (LSMO), LaSrCoO_{X} (LSCoO), and LaSrFeO_{X} (LSFeO), where x is nominally 3 for perovskites (e.g., x≦3 for perovskites) or the one or more CMO layers can be a conductive binary metal oxide structure comprised of a conductive binary metal oxide having the form A_{X}O_{Y}, where A represents a metal and O represents oxygen. The conductive binary oxide material may optionally be doped (e.g., with niobium Nb, fluorine F, and/or nitrogen N) to obtain the desired conductive properties for a CMO. Other suitable CMO materials are described in U.S. patent application Ser. No. 12/653,836, filed Dec. 18, 2009, and published as U.S. Pub. No. 2010/0157658, and titled “Conductive Metal Oxide Structures In Non-Volatile Re-Writable Memory Devices”, already incorporated herein by reference.

Thin-Film Deposition Techniques

Thin-film layers for the CMO, IMO, electrode structures, or other layers for the memory element (ME) and selection device (SD) described herein can be formed using a variety of microelectronics thin-film layer deposition techniques used for nanometer and sub-nanometer device fabrication, examples of which include, but are not limited to, physical vapor deposition (PVD), sputtering, reactive sputtering, co-sputtering, chemical vapor deposition (CVD), plasma enhanced chemical vapor deposition (PECVD), nano-deposition, atomic layer deposition (ALD), plasma enhanced atomic layer deposition (PEALD), gas cluster ion beam deposition (GCIB), combinations of those techniques, and the like, just to name a few. Further, some or all of the electrode structures can be formed using a plating process, such as electroless plating, for example.

For ALD or PEALD, a thin-film layer, such as an IMO layer and/or a CMO layer can be deposited in whole using ALD or PEALD, or can be deposited in part using ALD or PEALD and some other process, such as PVD or CVD can be used to in conjunction with the ALD or PEALD to deposit the IMO and/or CMO. Therefore, the CMO layer(s) can be deposited in whole or in part using ALD or PEALD and the IMO layers can be deposited in whole or in part using ALD or PEALD. Doping of one or more of the IMO layers and/or doping of the one or more layers of CMO can also be accomplished using the above deposition techniques or combination of those techniques. Doping can occur insitu as part of the deposition process (e.g., doping ceria oxide with gadolinium during the deposition of the ceria oxide).

In some embodiments, some or all of the IMO layers or one or more of the CMO layers are deposited insitu without a chamber break. That is, if there are three layers of IMO, than some or all of those three layers can be deposited insitu in the same deposition chamber. Similarly, if there are multiple layers of CMO, then some or all of those layers can be deposited insitu in the same deposition chamber. Variations in stoichiometry in general or as a function of layer thickness (see FIGS. 11A and 11B) can also be accomplished using the above deposition techniques and the deposition can be accomplished insitu.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

What is claimed is:

1. A memory device, comprising:
a discrete re-writeable non-volatile two-terminal memory element (ME) including
a first electrode structure,
a second electrode structure,
at least one layer of conductive metal oxide (CMO) in direct contact with the first electrode structure and including mobile oxygen ions, and
N distinct layers of insulating metal oxide (IMO) that are in direct contact with one another, N is an integer≧2, each layer of IMO has an individual layer thickness specifically configured for electron tunneling during data operations on the ME,
a first layer of the N distinct layers is in direct contact with the at least one layer of CMO and is made from an IMO material specifically configured to be non-reactive with a material of the at least one layer of CMO that the first layer is in direct contact with, the first layer is an electrolyte to and is permeable to the mobile oxygen ions during write operations to the ME,
a last layer of the N distinct layers is in direct contact with the second electrode structure, and
the at least one layer of CMO and the N distinct layers of IMO are directly electrically in series with one another and with the first and second electrode structures.

2. The memory device of claim 1, wherein at least one of the N distinct layers of IMO is made from a different IMO material.

3. The memory device of claim 1, wherein the N distinct layers of IMO include at least one pair of adjacent IMO layers that are made from IMO materials specifically configured to be non-reactive with each other.

4. The memory device of claim 1, wherein the N distinct layers of IMO include at least two IMO layers that have different band gaps.

5. The memory device of claim 4, wherein the at least two IMO layers that have different band gaps comprise adjacent IMO layers.

6. The memory device of claim 4, wherein a difference in band gap voltage between the different band gaps is approximately 1.0 eV or more.

7. The memory device of claim 4, wherein the at least two IMO layers that have different band gaps comprises a layer having a first band gap greater than or equal to about 5.0 eV and another layer having a second band gap less than or equal to about 3.0 eV.

8. The memory device of claim 7, wherein the layer comprises the first layer.

9. The memory device of claim 7, wherein the another layer comprises the first layer.

10. The memory device of claim 7, wherein the layer and the another layer comprise adjacent IMO layers.

11. The memory device of claim 1, wherein the first layer and an adjacent IMO layer comprise different IMO materials selected from the group consisting of a high-k dielectric material, cerium oxide, and gadolinium doped cerium oxide.

12. The memory device of claim 1, wherein the individual layer thickness for each distinct IMO layer does not vary by more than approximately 3.0 Angstroms.

13. The memory device of claim 1, wherein a selected one or more of the N distinct layers of IMO are deposited in whole or in part using atomic layer deposition (ALD).

14. The memory device of claim 1, wherein the N distinct layers of IMO are deposited in-situ in whole or in part using atomic layer deposition (ALD).

15. The memory device of claim 1, wherein a selected one or more of the N distinct layers of IMO comprise doped layers that are deposited in whole or in part using ALD.

16. The memory device of claim 1, wherein a selected one or more of the N distinct layers of IMO includes a stoichiometry that varies as a function of thickness within its respective individual layer thickness.

17. The memory device of claim 1, wherein other than the first layer, one or more of the N distinct layers of IMO is an electrolyte to and is permeable to the mobile oxygen ions during write operations to the ME.

18. The memory device of claim 17, wherein other than the first layer, one or more of the N distinct layers of IMO is less permeable to the mobile oxygen ions than the first layer.

19. The memory device of claim 1, wherein a combined thickness of all the N distinct layers of IMO is approximately 40 Angstroms or less.

20. The memory device of claim 1, wherein the at least one layer of CMO comprises a plurality of CMO layers and two or more of the plurality of CMO layers are made from different CMO materials.

21. The memory device of claim 20, wherein the plurality of CMO layers have different layer thicknesses and the first layer is in direct contact with the thinnest layer of the plurality of CMO layers.

22. The memory device of claim 1 and further comprising: a plurality of the ME's and the individual layer thickness for each of the N distinct layers of IMO does not vary in thickness by more than approximately 3.0 Angstrom among the plurality of the ME's.

23. The memory device of claim 1 and further comprising: a plurality of the ME's and the individual layer thickness for each of the N distinct layers of IMO does not vary in thickness by more than approximately 3.0 Angstroms among the plurality of the ME's.

24. The memory device of claim 1, wherein at least a portion of the first electrode structure, the second electrode structure or both comprises a non-reactive metal or an alloy of a non-reactive metal.

25. The memory device of claim 1, wherein the first electrode structure, the second electrode structure or both comprises at least two layers of an electrically conductive material.

26. The memory device of claim 1, wherein the at least one layer of CMO is deposited in whole or in part using ALD.

27. The memory device of claim 1, wherein one or more of the N distinct layers of IMO comprises a soft-blended multi-phase IMO layer.

28. A memory device, comprising:
a discrete re-writeable non-volatile two-terminal memory element (ME) including
a first electrode structure,
a second electrode structure,
at least one layer of conductive metal oxide (CMO) in direct contact with the first electrode structure and including mobile oxygen ions, and
N distinct layers of insulating metal oxide (IMO) that are in direct contact with one another, N is an integer≧2, each layer of IMO has an individual layer thickness specifically configured for electron tunneling during data operations on the ME,
a first layer of the N distinct layers is in direct contact with the at least one layer of CMO and the first layer is an electrolyte to and is permeable to the mobile oxygen ions during write operations to the ME,
a last layer of the N distinct layers is in direct contact with the second electrode structure, and
at least two adjacent IMO layers in the N distinct layers have different band gaps operative to generate an internal electric field positioned in the at least two adjacent IMO layers and present in the at least two adjacent IMO layers in the absence of electrical power,
the at least one layer of CMO and the N distinct layers of IMO are directly electrically in series with one another and with the first and second electrode structures.

29. The memory device of claim 28, wherein the at least two adjacent IMO layers are made from different IMO materials.

30. The memory device of claim 28, wherein the internal electric field comprises a static electric field.

31. The memory device of claim 28, wherein a difference in band gap voltage between the different band gaps is approximately 1.0 eV or more.

32. The memory device of claim 28, wherein at least two of the N distinct layers of IMO are made from different IMO materials.

33. The memory device of claim 28, wherein the at least one layer of CMO comprises a plurality of CMO layers and two or more of the plurality of CMO layers are made from different CMO materials.

34. The memory device of claim 33, wherein the plurality of CMO layers have different layer thicknesses and the first layer is in direct contact with the thinnest layer of the plurality of CMO layers.

35. The memory device of claim 28, wherein the at least one layer of CMO is deposited in whole or in part using atomic layer deposition (ALD).

36. The memory device of claim 28, wherein a selected one or more of the N distinct layers of IMO are deposited in whole or in part using atomic layer deposition (ALD).

37. The memory device of claim 28, wherein a selected one or more of the N distinct layers of IMO includes a stoichiometry that varies as a function of thickness within its respective individual layer thickness.

38. The memory device of claim 28, wherein two adjacent layers of the N distinct layers of IMO have different band gaps and comprises a layer having a first band gap greater than or equal to about 5.0 eV and another layer having a second band gap less than or equal to about 3.0 eV, and the internal electric field is positioned in the two adjacent layers.

39. The memory device of claim 28, wherein the first layer and an adjacent IMO layer comprise different IMO materials selected from the group consisting of a high-k dielectric material, cerium oxide, and gadolinium doped cerium oxide.

40. The memory device of claim 28, wherein the individual layer thickness for each distinct IMO layer does not vary by more than approximately 3.0 Angstroms.

41. The memory device of claim 28, wherein a combined thickness of all the N distinct layers of IMO is approximately 40 Angstroms or less.

42. The memory device of claim 28, wherein one or more of the N distinct layers of IMO comprises a soft-blended multi-phase IMO layer.
